(19) United States
(12) Patent Application Publication
(10) Pub. No.: US 2024/0074064 A1
(43) Pub. Date: Feb. 29, 2024

(54) METHOD FOR STRUCTURING METAL-CERAMIC SUBSTRATES, AND STRUCTURED METAL CERAMIC SUBSTRATE

(71) Applicant: Heraeus Deutschland GmbH & Co. KG, HANAU (DE)

(72) Inventors: Richard WACKER, Hanau (DE); Daniel SCHNEE, Hanau (DE); Andre SCHWÖEBEL, Hanau (DE); Juergen SCHARF, Hanau (DE)

(21) Appl. No.: 18/261,607

(22) PCT Filed: Nov. 5, 2021
(86) PCT No.: PCT/EP2021/080735

§ 371 Date: Jul. 14, 2023

(30) Foreign Application Priority Data
Jan. 22, 2021 (EP) 21152896.3

(51) Int. Cl. H05K 3/00; C23F 1/18; H05K 1/03; H05K 3/06

(52) U.S. Cl. CPC H05K 3/002; C23F 1/18; H05K 1/0306; H05K 3/061; H05K 3/068; H05K 2203/0147; H05K 2203/1527; H05K 2203/1545

(57) ABSTRACT

The invention relates to a method for structuring metal-ceramic substrates and to a structured metal-ceramic substrate which can be used in particular in power electronics. In the method, a first metal-ceramic substrate and a second metal-ceramic substrate are etched, wherein, while being contacted with an etching solution that is capable of removing active metal from the bonding layer of the metal-ceramic substrates, the first metal-ceramic substrate and the second metal-ceramic substrate are positioned such that an orthogonal projection of the first metal-ceramic substrate onto a projection plane parallel to the metal layer of the first metal-ceramic substrate shades no more than 60% of the metal layer of the second metal-ceramic substrate.

The present invention relates to a method for structuring metal-ceramic substrates and to a structured metal-ceramic substrate.

Metal-ceramic substrates play an important role in the field of power electronics. They are a crucial element in the construction of electronic components and ensure rapid dissipation of high amounts of heat during the operation of these components. Metal-ceramic substrates usually consist of a ceramic layer and a metal layer which is bonded to the ceramic layer.

Several methods are known from the prior art for bonding the metal layer to the ceramic layer. In the so-called direct copper bonding (DCB) method, a copper foil is provided superficially with a copper compound (usually copper oxide) having a lower melting point than copper by reaction of copper with a reactive gas (usually oxygen). If the copper foil treated in this way is applied to a ceramic body and the composite is fired, the copper compound melts and wets the surface of the ceramic body so that a stable material bond occurs between the copper foil and the ceramic body. This method is described, for example, in U.S. Pat. No. 3,744,120 A or DE 2319854 C2.

Despite obvious advantages, the DCB method has two main disadvantages. Firstly, the method must be carried out at relatively high temperatures, specifically somewhat below the melting point of copper. Secondly, the method can be used only for aluminum-based ceramics such as aluminum oxide or aluminum nitride. Therefore, there is a need for an alternative method for producing metal-ceramic substrates under less stringent conditions. In an alternative method, metal foils can be bonded to ceramic bodies at temperatures of approximately 650 to 1000° C., a specific solder being used that usually contains silver and/or copper and an active metal. The role of the active metal is to react with the ceramic material and thus to enable a bonding of the ceramic material to the remaining solder to form a reaction layer, while the copper and/or silver is used to bond this reaction layer to the metal foil. For example, JP4812985 B2 proposes bonding a copper foil to a ceramic body using a solder which contains 50 to 89 wt. % silver and also copper, bismuth, and an active metal. With this method, it is possible to join the copper foil reliably to the ceramic body. To avoid problems associated with migration of silver, it can be advantageous to use silver-free solders to bond metal foils to ceramic bodies. Such a technique is proposed, for example, in DE 102017114893 A1. The metal-ceramic substrates produced in this way therefore have, in addition to a metal layer and a ceramic layer, a bonding layer which lies between the metal layer and the ceramic layer and contains an active metal.

After the metal foil is bonded to the ceramic body, the resulting metal-ceramic substrate is usually structured for the construction of conductor tracks. Conventional etching techniques are generally used for this purpose. According to a common method, the metal surface of the metal-ceramic substrate is provided with masking, for example with a polymer. This masking protects the areas of the metal-ceramic substrate that are not to be removed in the subsequent etching step, while the unmasked areas are accessible for etching. During etching, the metal of the metal foil and the components of the bonding layer are then dissolved using a plurality of etching solutions and removed from the metal-ceramic substrate, resulting in conductor tracks. Subsequently, the masking is removed, resulting in a structured metal-ceramic substrate.

According to a conventional method, the metal of the metal foil and components of the solder of the bonding layer are removed during the treatment with a first etching solution, at least the active metal remaining. The active metal is subsequently dissolved and removed by treatment with a second etching solution. In order to achieve the highest possible throughput, the metal-ceramic substrates are usually stacked in a holding device and contacted with the etching solutions in the holding device. The vertical stacking of the metal-ceramic substrates has proven to be particularly advantageous for practical reasons. In order to ensure complete etching, the metal-ceramic substrates must be contacted with the etching solutions for an extended period of time.

In principle, there is a need to reduce the residence time of the metal-ceramic substrates in the etching solutions. The method for structuring metal-ceramic substrates could thus be carried out more quickly, more efficiently, and in a more resource- and energy-efficient manner. Furthermore, there is a need to achieve as complete a removal as possible of the material to be removed during etching, in particular the active metal, within a predetermined time.

The object of the present invention is therefore to provide a simple method for structuring metal-ceramic substrates. This method should preferably be faster, more efficient, more resource-efficient and/or more energy-efficient than the methods known from the prior art. Furthermore, it is preferred for the method to result in the most complete possible removal of the material to be removed during etching, in particular the active metal, within a predetermined time.

This object is achieved by the method of claim 1.

The invention therefore provides a method for structuring metal-ceramic substrates, comprising the steps of:
a) providing a first metal-ceramic substrate and a second metal-ceramic substrate, each comprising
   a ceramic layer,
   a metal layer, and
   a bonding layer located between the ceramic layer and the metal layer, wherein the bonding layer comprises (i) a metal having a melting point of at least 700° C. and (ii) an active metal,
b) providing an etching solution 1 that is capable of removing the metal from the metal layer and at least partly removing the metal having a melting point of at least 700° C. from the bonding layer,
c) providing an etching solution 2 that is capable of removing the active metal from the bonding layer,
d) masking regions on the metal layer of the first metal-ceramic substrate and on the metal layer of the second metal-ceramic substrate that are not intended to be removed,
e) contacting the first metal-ceramic substrate and the second metal-ceramic substrate with the etching solution 1, and
f) contacting the first metal-ceramic substrate and the second metal-ceramic substrate with the etching solution 2, wherein the first metal-ceramic substrate and the second metal-ceramic substrate are positioned such that an orthogonal projection of the first metal-ceramic substrate onto a projection plane parallel to the metal layer of the first metal-ceramic substrate shades no more than 60% of the metal layer of the second metal-ceramic substrate.

Furthermore, the invention provides a metal-ceramic substrate obtainable by this method.

The method according to the invention relates to the structuring of metal-ceramic substrates.

To this end, a first metal-ceramic substrate and a second metal-ceramic substrate are first provided.

The first and second metal-ceramic substrates each comprise a metal layer. The metal of the metal layer is preferably selected from the group consisting of copper, aluminum, and molybdenum. According to a particularly preferred embodiment, the metal of the metal layer is selected from the group consisting of copper and molybdenum. According to a very particularly preferred embodiment, the metal of the metal layer is copper. The metal layer preferably has a thickness in the range of 0.01-10 mm, more preferably in the range of 0.03-5 mm, and particularly preferably in the range of 0.05-3 mm.

The first and second metal-ceramic substrates each comprise a ceramic layer. The ceramic of the ceramic layer is preferably an insulating ceramic. The ceramic can be, for example, an oxide ceramic, a nitride ceramic or a carbide ceramic. Preferably, the ceramic is a metal oxide ceramic, a silicon oxide ceramic, a metal nitride ceramic, a silicon nitride ceramic, a boron nitride ceramic or a boron carbide ceramic. According to a preferred embodiment, the ceramic is selected from the group consisting of aluminum nitride ceramics, silicon nitride ceramics, and aluminum oxide ceramics (such as zirconia toughened alumina (ZTA) ceramics). The ceramic layer preferably has a thickness of 0.05-10 mm, more preferably in the range of 0.1-5 mm, and even more preferably in the range of 0.15-3 mm.

The first metal-ceramic substrate and the second metal-ceramic substrate each comprise a bonding layer located between the ceramic layer and the metal layer. The bonding layer preferably produces an integral bond between the ceramic layer and the metal layer.

The bonding layer comprises (i) a metal having a melting point of at least 700° C. and (ii) an active metal. The metal having a melting point of at least 700° C. preferably has a melting point of at least 850° C. and more preferably a melting point of at least 1000° C. According to a preferred embodiment, the metal having a melting point of at least 700° C. is selected from the group consisting of copper, silver, nickel, tungsten, molybdenum, and mixtures thereof. According to a particularly preferred embodiment, the metal having a melting point of at least 700° C. is selected from the group consisting of copper, nickel, tungsten, molybdenum, and mixtures thereof. According to a very particularly preferred embodiment, the metal having a melting point of at least 700° C. is copper. The content of the at least one metal having a melting point of at least 700° C. is preferably 55-93 atomic percent, particularly preferably 60-85 atomic percent and very particularly preferably 65-80 atomic percent, based on the number of atoms in the bonding layer.

The active metal is preferably selected from the group consisting of titanium, zirconium, niobium, tantalum, vanadium, hafnium, and mixtures thereof. According to a particularly preferred embodiment, the active metal is titanium. The content of the active metal is preferably 1-10 atomic percent, particularly preferably 2-8 atomic percent and very particularly preferably 3-7 atomic percent, based on the number of atoms in the bonding layer.

According to a preferred embodiment, in addition to (i) a metal having a melting point of at least 700° C. and (ii) an active metal, the bonding layer can comprise (iii) further elements as the remainder. According to a particularly preferred embodiment, the content of further elements in the bonding layer is 5-40 atomic percent, more preferably 7-35 atomic percent and particularly preferably 10-35 atomic percent, based on the number of atoms in the bonding layer.

In accordance with a further preferred embodiment, the bonding layer comprises a metal having a melting point of less than 700° C. The metal having a melting point of less than 700° C. preferably has a melting point of less than 600° C. and particularly preferably a melting point of less than 550° C. According to a preferred embodiment, the metal having a melting point of less than 700° C. is selected from the group consisting of tin, bismuth, indium, gallium, zinc, antimony, magnesium, and mixtures thereof. According to a particularly preferred embodiment, the metal having a melting point of less than 700° C. is selected from the group consisting of tin, bismuth, and mixtures thereof. The content of the at least one metal having a melting point of less than 700° C. is preferably 5-40 atomic percent, more preferably 7-atomic percent, and particularly preferably 10-35 atomic percent, based on the number of atoms in the bonding layer.

According to a preferred embodiment, the bonding layer comprises a region close to the metal layer and a region close to the ceramic layer. The region close to the metal layer is preferably richer in the metal having a melting point of at least 700° C. than the region near the ceramic layer. The region close to the ceramic layer is preferably richer in active metal than the region close to the metal layer. According to a particularly preferred embodiment, the region close to the metal layer is thicker than the region of the bonding layer close to the ceramic layer. In this case, it can be preferred for the ratio of the thickness of the region of the bonding layer close to the metal layer to the thickness of the region of the bonding layer close to the ceramic layer to be at least 2: 1, even more preferably at least 3: 1, and particularly preferably at least 5: 1.

According to a preferred embodiment, the maximum silver content is preferably 15.0 atomic percent, more preferably 1.0 atomic percent, even more preferably 0.5 atomic percent and very particularly preferably 0.1 atomic percent, based on the number of atoms in the bonding layer. Accordingly, it may be preferable for the bonding layer to be silver-free or low in silver. Surprisingly, it has been found that the absence of silver in the bonding layer or only a small content of silver in the bonding layer means that a reliable and complete removal of the active metal from the region of the bonding layer to be etched by the method according to the invention can be achieved in a shorter time. Without wishing to be bound by theory, this effect could be attributed to the fact that the presence of silver favors the formation of a region close to the metal layer that is difficult to remove by etching. The formation of this silver-containing region close to the metal layer could ultimately mean that the contacting of the active metal-containing region close to the ceramic layer with the etching solution 2 is effectively blocked. This blocking would be reduced or even eliminated by reducing the amount of silver in the bonding layer, making it easier to remove the active metal.

According to a preferred embodiment, the first metal-ceramic substrate and the second metal-ceramic substrate each comprise
a second metal layer, and
a second bonding layer located between the ceramic layer and the second metal layer, wherein the second bonding layer comprises (i) a metal having a melting point of at least 700° C. and (ii) an active metal.

Metal-ceramic substrates of this kind are also referred to as double-sided metalized metal-ceramic substrates. For the features of the second metal layer and the second bonding layer, reference can be made to the embodiments described herein for the metal layer and the bonding layer. Preferably, therefore, the second metal layer is formed like the metal layer described herein, and the second bonding layer is formed like the bonding layer described herein.

The metal-ceramic substrates can be produced by a conventional method known from the prior art. The metal-ceramic substrates are preferably produced by means of a soldering method. According to a preferred embodiment, the metal-ceramic substrates are produced by means of an AMB (“Active Metal Brazing”) method. In this method, a metal foil is usually soldered to a ceramic body using a solder material comprising copper, silver and an active metal (for example titanium). Such a method is disclosed, for example, in U.S. Pat. No. 4,591,535 A. According to a further preferred embodiment, the metal-ceramic substrates are produced by means of a method in which a metal foil is soldered to a ceramic body using a solder material comprising a metal having a melting point of at least 700° C. (for example copper), a metal having a melting point of less than 700° C. (for example tin) and an active metal (for example titanium). Such a method is disclosed, for example, in DE 102017114893 A1.

In the method according to the invention, an etching solution 1 is provided that is capable of removing the metal from the metal layer and at least partly removing the metal having a melting point of at least 700° C. from the bonding layer. For example, the etching solution 1 can be an etching solution known from the prior art and suitable for the etching of copper. For example, the etching solution 1 can therefore be selected from the group consisting of FeCl₃ etching solutions and CuCl₂ etching solutions.

In the method according to the invention, an etching solution 2 is also provided that is capable of removing the active metal from the bonding layer. The etching solution 2 can be an etching solution for active metals known from the prior art. Exemplary etching solutions are disclosed in EP3688835 A1 and EP3684148 A1. According to a preferred embodiment, etching solution 2 is selected from the group consisting of etching solutions containing hydrogen peroxide and etching solutions containing ammonium peroxydisulfate. For example, etching solution 2 can be an etching solution that contains ammonium fluoride and fluoroboric acid (for example HBF₄) as well as hydrogen peroxide and/or ammonium peroxydisulfate.

According to the invention, regions on the first metal-ceramic substrate and the second metal-ceramic substrate that are not intended to be removed are masked. The masking is not further restricted and can be carried out in a manner known to a person skilled in the art from the prior art. For example, an etch resist may be used for masking. For example, it is possible to apply an etch resist to the metal layer of the metal-ceramic substrate and to expose for curing only the regions that are not intended to be removed. During the subsequent contact with the etching solutions, the masked regions are protected, such that no material removal due to the action of the etching solutions takes place in these regions. In contrast, the unmasked (uncured) regions are accessible for etching in the subsequent etching step.

According to the present invention, the first metal-ceramic substrate and the second metal-ceramic substrate are subsequently contacted with the etching solution 1. In this step, the metal from the metal layer and at least partly the metal having a melting point of at least 700° C. is removed from the bonding layer in the unmasked regions of the metal-ceramic substrates due to the action of etching solution 1. Furthermore, the etching solution 1 can also be designed such that, in addition to the metal of the metal layer and the metal having a melting point of at least 700° C., further metals of the bonding layer, if present, are removed with the exception of the active metal. There are no further restrictions on the way in which the metal-ceramic substrates are contacted with the etching solution 1. It can preferably be provided for the metal-ceramic substrates to be immersed in or sprayed with the etching solution 1.

In the method according to the invention, the first metal-ceramic substrate and the second metal-ceramic substrate are subsequently contacted with the etching solution 2. In this step, the active metal is removed in the unmasked regions of the metal-ceramic substrates due to the action of etching solution 2. In this case, the first metal-ceramic substrate and the second metal-ceramic substrate are positioned such that an orthogonal projection of the first metal-ceramic substrate onto a projection plane parallel to the metal layer of the first metal-ceramic substrate shades no more than 60% of the metal layer of the second metal-ceramic substrate. According to a preferred embodiment, the first metal-ceramic substrate and the second metal-ceramic substrate are contacted with the etching solution 2, the first metal-ceramic substrate and the second metal-ceramic substrate being positioned such that an orthogonal projection of the first metal-ceramic substrate onto a projection plane parallel to the metal layer of the first metal-ceramic substrate shades no more than 50%, particularly preferably no more than 40%, very particularly preferably no more than 30%, and, for example, no more than 15% of the metal layer of the second metal-ceramic substrate.

The orthogonal projection of the first metal-ceramic substrate takes place onto a projection plane that runs parallel to the metal layer of the first metal-ceramic substrate. Preferably, the projection plane is a plane spanned by an image obtained by parallel displacement of the first metal-ceramic substrate. The displacement preferably takes place in a perpendicular direction to the metal layer of the first metal-ceramic substrate. This parallel displacement can take place in one direction and in the opposite direction. The distance between the metal layer of the first metal-ceramic substrate and the projection plane parallel thereto is preferably selected such that the distance between the metal layer of the first metal-ceramic substrate and the projection plane parallel thereto is greater than or equal to the distance between the metal layer of the first metal-ceramic substrate and a plane that is spanned by the second metal-ceramic substrate, the distance between the metal layer of the first metal-ceramic substrate and a plane that is spanned by the second metal-ceramic substrate preferably being determined along a perpendicular through the centroid of the metal layer of the first metal-ceramic substrate. The distance between the metal layer of the first metal-ceramic substrate and the projection plane parallel thereto is therefore preferably large enough to be able to achieve a partial shading of the second metal-ceramic substrate during an orthogonal projection, if this is possible at all due to the arrangement of the first metal-ceramic substrate and the second metal-ceramic substrate. For example, the distance between the metal layer of the first metal-ceramic substrate and the projection plane parallel thereto can be equal to the largest side length of the first metal-ceramic substrate. For example, the distance between the metal layer of the first metal-ceramic substrate and the projection plane parallel thereto can be 20 cm, 30 cm or 50 cm.

If the second metal-ceramic substrate is located between the metal layer of the first metal-ceramic substrate and the projection plane parallel thereto, the metal layer of said second metal-ceramic substrate can be shaded, optionally in part, by the orthogonal projection. According to the invention, shading is present independently of whether the metal layer of the first metal-ceramic substrate faces toward or away from the metal layer of the second metal-ceramic substrate. Shading of the metal layer of the second metal-ceramic substrate can therefore also be achieved when the ceramic layer of the first metal-ceramic substrate, the ceramic layer of the second metal-ceramic substrate, the ceramic layers of the first and second metal-ceramic substrates, or optionally objects bonded to the ceramic layer of the first or second metal-ceramic substrate (for example, a further metal layer on the first and/or second metal-ceramic substrate) are still located in the orthogonal projection between the metal layer of the first metal-ceramic substrate and the metal layer of the second metal-ceramic substrate. The shading ratio is preferably obtained from the ratio of (a) to (b), (a) indicating the area of the region on the second metal-ceramic substrate cut through the orthogonal projection of the first metal-ceramic substrate onto a projection plane parallel to the metal layer of the first metal-ceramic substrate, and (b) indicating the area of the metal layer of the second metal-ceramic substrate. Any masking of a metal layer is not to be taken into account in the area calculation. Therefore, the area of the metal layer that would result without masking and etching is preferably used for the area calculation. Likewise, any further metal layer on the second metal-ceramic substrate, as is present for example in the case of a double-sided metallization, is not to be taken into account in the area calculation.

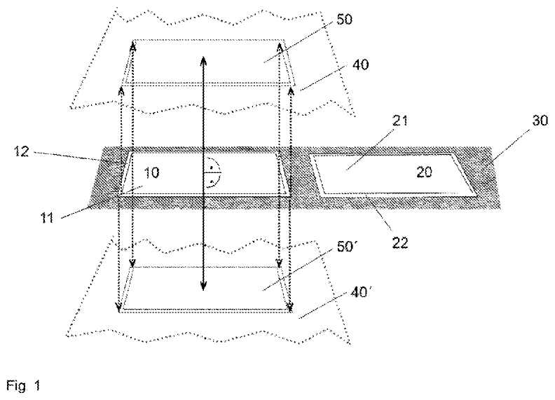

FIG. 1 shows an arrangement of a first metal-ceramic substrate 10 and a second metal-ceramic substrate 20, an orthogonal projection of the first metal-ceramic substrate 10 onto a projection plane 40, 40′ parallel to the masked metal layer 11 of the first metal-ceramic substrate 10 shading 0% of the metal layer 21 of the second metal-ceramic substrate 20. Shown is a first metal-ceramic substrate 10 comprising a masked (not shown) metal layer 11 bonded to a ceramic layer 12. The ceramic layer 12 can have a larger dimension than the metal layer 11 and thus extend beyond the metal layer 11. Also shown is a second metal-ceramic substrate 20 comprising a metal layer 21 bonded to a ceramic layer 22. The first metal-ceramic substrate 10 and the second metal-ceramic substrate 20 lie horizontally on a carrier 30 over their entire area. A parallel displacement of the first metal-ceramic substrate 10 perpendicular to the metal layer 11 of the first metal-ceramic substrate 10 results in an image 50, 50′ of the first metal-ceramic substrate 10 that spans a projection plane 40, 40′. An orthogonal projection (indicated by dashed arrows) of the first metal-ceramic substrate 10 onto the projection plane 40, 40′ does not intersect the metal layer 21 of the second metal-ceramic substrate 20. The shading of the second metal-ceramic substrate 20 by an orthogonal projection of the first metal-ceramic substrate 10 onto a projection plane 40, 40′ parallel to the metal layer 11 of the first metal-ceramic substrate 10 is therefore 0%.

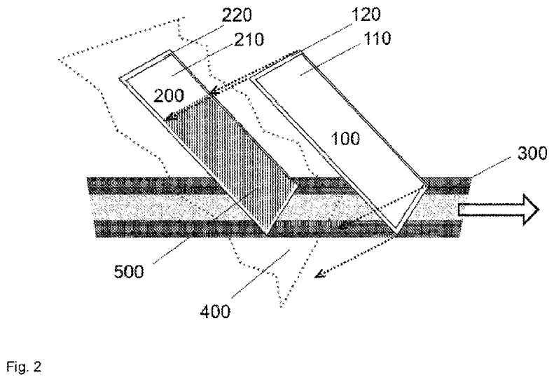

FIG. 2 shows an arrangement of a first metal-ceramic substrate 100 and a second metal-ceramic substrate 200, an orthogonal projection of the first metal-ceramic substrate 100 onto a projection plane 400 parallel to the masked metal layer 110 of the first metal-ceramic substrate 100 shading more than 60% of the metal layer 210 of the second metal-ceramic substrate 200. Shown is a first metal-ceramic substrate 100 having a masked (not shown) metal layer 110 bonded to a ceramic layer 120. Also shown is a second metal-ceramic substrate 200 having a metal layer 210 bonded to a ceramic layer 220. The first metal-ceramic substrate 100 and the second metal-ceramic substrate 200 are positioned obliquely on a carrier 300 (e.g., a conveyor belt). The oblique arrangement can be achieved, for example, by means of a support (not shown). The second metal-ceramic substrate 200 is arranged behind the first metal-ceramic substrate 100 and oriented parallel thereto. A projection plane 400 is spaced apart parallel from the masked metal layer 110 of the first metal-ceramic substrate 100. Said projection plane can be spanned here, for example, by the second metal-ceramic substrate 200 because said second metal-ceramic substrate is arranged parallel to the masked metal layer 110 of the first metal-ceramic substrate 100. However, the position of the projection plane is not further restricted. Thus, the projection plane can alternatively also be displaced parallel to the projection plane 400 shown here. Said projection plane can in particular be selected such that it has a greater distance from the metal surface 110 of the metal-ceramic substrate 100 than the projection surface 400. The shading ratio of the second metal-ceramic substrate 200 by an orthogonal projection of the first metal-ceramic substrate 100 onto a projection plane parallel to the metal layer 110 of the first metal-ceramic substrate 110 is thus independent of the exact position of the projection surface. An orthogonal projection (indicated by dashed arrows) of the first metal-ceramic substrate 100 onto the projection plane 400 intersects the metal layer 210 of the second metal-ceramic substrate 200 in the hatched region 500. The shading of the second metal-ceramic substrate 200 by an orthogonal projection of the first metal-ceramic substrate 100 onto a projection plane 400 parallel to the metal layer 110 of the first metal-ceramic substrate 100 is greater than 60%.

Surprisingly, it has been found that the relative position of the individual metal-ceramic substrates with respect to one another has a considerable influence on the effectiveness of the etching with etching solution 2. According to the invention, an arrangement of the metal-ceramic substrates that ensures that the surfaces of the metal-ceramic substrates with the unmasked regions (i.e., for example, the regions not occupied by an etching mask) are as freely accessible as possible to the etching solution 2 is advantageous. Without wishing to be bound by theory, this could be due to the fact that the etching solution 2 can be applied optimally to the unmasked regions in this way. An effective application of etching solution 2 could in turn mean that the contacting with etching solution 2 already results in complete removal of the active metal from the bonding layer within a very short period of time.

The arrangement of the first metal-ceramic substrate and the second metal-ceramic substrate during contact with the etching solution 2 is not further restricted. According to a preferred embodiment, the first metal-ceramic substrate and the second metal-ceramic substrate are contacted with the etching solution 2 while the first metal-ceramic substrate and the second metal-ceramic substrate are moved. Preferably, the movement is a continuous movement.

According to a preferred embodiment, the first metal-ceramic substrate and the second metal-ceramic substrate are positioned on a carrier for contacting with etching solution 2. Particularly preferably, the first metal-ceramic substrate and the second metal-ceramic substrate are arranged on the same carrier. For example, the carrier can be a conveyor belt. According to a preferred embodiment, the carrier is a conveyor belt that is moved in a conveying direction. On the other hand, the carrier can also be a holder for metal-ceramic substrates that rests on a conveyor belt. For example, the first metal-ceramic substrate and the second metal-ceramic substrate can therefore be arranged directly on the conveyor belt as a carrier, or the first metal-ceramic substrate and the second metal-ceramic substrate can be arranged on a further carrier (e.g., a holder) that is in turn arranged on the conveyor belt as a carrier.

The arrangement of the first metal-ceramic substrate and the second metal-ceramic substrate on a carrier is not further restricted. According to a preferred embodiment, it is provided that the first metal-ceramic substrate and the second metal-ceramic substrate rest on one of the carriers over their entire area. Alternatively, it can be provided that the first metal-ceramic substrate and the second metal-ceramic substrate rest substantially only on guide rails of a conveyor belt. According to a further alternative, the first metal-ceramic substrate and the second metal-ceramic substrate can rest on guide rails of a further carrier (e.g., a holder) or be clamped in a frame of a further carrier (e.g., a holder), and said carrier can be arranged on a conveyor belt.

Preferably, the metal-ceramic substrates rest on a carrier such that the metal layers of the first metal-ceramic substrate and the second metal-ceramic substrate provided with the masking and preferably provided for the treatment with the etching solution 2 face away from the carrier. According to a further preferred embodiment, the first metal-ceramic substrate and the second metal-ceramic substrate are each double-sided metalized metal substrates, particular preference being given to double-sided masking of regions on the metal layers of the first metal-ceramic substrate and of regions on the metal layers of the second metal-ceramic substrate. In this embodiment, a configuration can be advantageous in which the metal-ceramic substrates rest on a carrier, for example on guide rails of a conveyor belt or on guide rails of a holder, or are clamped in a frame of a holder only at the edges for treatment with etching solution.

The possibilities of arranging the first metal-ceramic substrate and the second metal-ceramic substrate such that, during contacting with the etching solution 2, an orthogonal projection of the first metal-ceramic substrate onto a projection plane parallel to the metal layer of the first metal-ceramic substrate shades no more than 60% of the metal layer of the second metal-ceramic substrate are not further restricted.

According to a preferred embodiment, while being contacted with the etching solution 2, the first metal-ceramic substrate and the second metal-ceramic substrate are positioned on a carrier, preferably on the same carrier, in at least one of the following ways, the carrier preferably being a conveyor belt, which is particularly preferably moved in a conveying direction:
a) the first metal-ceramic substrate and the second metal-ceramic substrate are not stacked;
b) the first metal-ceramic substrate and the second metal-ceramic substrate are arranged in a substantially horizontal position;
c) the first metal-ceramic substrate and the second metal-ceramic substrate are arranged in a substantially vertical position and one after another with respect to the conveying direction;
d) the first metal-ceramic substrate and the second metal-ceramic substrate are positioned such that the first metal-ceramic substrate and the conveying direction form an angle that is no more than 45°, more preferably no more than 30°, and even more preferably no more than 20°, and the second metal-ceramic substrate and the conveying direction form an angle that is no more than 45°, more preferably no more than 30°, and even more preferably no more than 20°.

Accordingly, the first metal-ceramic substrate and the second metal-ceramic substrate cannot be stacked according to one embodiment while being contacted with etching solution 2. In this case, the first metal-ceramic substrate and the second metal-ceramic substrate are preferably arranged next to each other. Preferably, the first metal-ceramic substrate and the second metal-ceramic substrate are arranged parallel to one another.

According to a further preferred embodiment, the first metal-ceramic substrate and the second metal-ceramic substrate are arranged in a substantially horizontal position. In this case, the first metal-ceramic substrate and the second metal-ceramic substrate are preferably arranged next to each other. Preferably, the first metal-ceramic substrate and the second metal-ceramic substrate are arranged parallel to one another. For example, in this case, the first metal-ceramic substrate and the second metal-ceramic substrate can each be arranged lying on one of their metal layers, particularly preferably on the unmasked metal layer.

According to a further preferred embodiment, the first metal-ceramic substrate and the second metal-ceramic substrate are arranged in a substantially vertical position and one after another with respect to the conveying direction. In this case, for example, the first metal-ceramic substrate and the second metal-ceramic substrate can be arranged in a holder on the conveyor belt. In this case, the first metal-ceramic substrate and the second metal-ceramic substrate can be arranged in the same holder or the first metal-ceramic substrate and the second metal-ceramic substrate can be arranged in different holders. In this case, the first metal-ceramic substrate and the second metal-ceramic substrate are arranged one after another with respect to the conveying direction, such that an ideal application of the etching solution 2 can take place.

According to a further preferred embodiment, the first metal-ceramic substrate and the second metal-ceramic substrate are positioned such that the first metal-ceramic substrate and the conveying direction form an angle that is no more than 45°, more preferably no more than 30°, and even more preferably no more than 20°, and the second metal-ceramic substrate and the conveying direction form an angle that is no more than 45°, more preferably no more than 30°, and even more preferably no more than 20°. According to yet another preferred embodiment, the first metal-ceramic substrate and the second metal-ceramic substrate are positioned such that the first metal-ceramic substrate and the conveying direction form an angle that is at least 1°, more preferably at least 3° and particularly preferably at least 5°, and the second metal-ceramic substrate and the conveying direction form an angle that is at least 1°, more preferably at least 3° and particularly preferably at least 5°. Such an angle between the first or second metal-ceramic substrate and the conveying direction of the conveyor belt can be advantageous to facilitate the drainage of the etching solution 2. According to yet another preferred embodiment, the first metal-ceramic substrate and the second metal-ceramic substrate are arranged such that the first metal-ceramic substrate and the conveying direction form an angle in the range of 1-45°, more preferably an angle in the range of 3-30°, and particularly preferably an angle in the range of 5-20°, and the second metal-ceramic substrate and the conveying direction form an angle in the range of 1-45°, more preferably an angle in the range of 3-30°, and particularly preferably an angle in the range of 5-20°.

According to a further preferred embodiment, the method according to the invention is carried out in a continuous manner.

There are no further restrictions on the way in which the first metal-ceramic substrate and the second metal-ceramic substrate are contacted with the etching solution 2. According to a preferred embodiment, the first metal-ceramic substrate and the second metal-ceramic substrate are contacted with the etching solution 2 by spraying the first metal-ceramic substrate and the second metal-ceramic substrate with the etching solution 2, by immersing the first metal-ceramic substrate and the second metal-ceramic substrate in etching solution 2, or by passing the first metal-ceramic substrate and the second metal-ceramic substrate through the etching solution 2.

According to yet another preferred embodiment, the first metal-ceramic substrate and the second metal-ceramic substrate are contacted with ultrasound during the contacting with the etching solution 2.

According to a preferred embodiment, the masking is removed from the first metal-ceramic substrate and from the second metal-ceramic substrate. For example, the masking can be removed from the first metal-ceramic substrate and from the second metal-ceramic substrate after contacting with etching solution 2. On the other hand, it is also possible to remove the masking from the first metal-ceramic substrate and from the second metal-ceramic substrate after contacting with etching solution 1. The removal of the masking is not further restricted and can take place in a manner known to a person skilled in the art.

Furthermore, it can be advantageous if washing is performed before, between and/or after individual steps of the method according to the invention. The washing is preferably performed with water. Particularly preferably, the first metal-ceramic substrate and the second metal-ceramic substrate are washed
before masking,
before treatment with etching solution 1,
before treatment with etching solution 2,
before removal of the masking and/or
after removal of the masking.

After the washing, the first metal-ceramic substrate and the second metal-ceramic substrate are preferably dried.

A metal-ceramic substrate obtained by the method described above has particularly fine structuring and is highly suitable for use in power electronics.

### EMBODIMENTS

### Example for Producing Metal-Ceramic Substrates

For the production of metal-ceramic substrates, 19.8 percent by weight of tin powder (7-11 μm), 3.7 percent by weight of titanium hydride and 6.5 percent by weight of an organic vehicle were first mixed in a standing mixer at 1930 rpm for 30 minutes. Thereafter, 3.0 percent by weight of Texanol and 67 percent by weight of copper powder (7-11 μm) were added in increments. The mixture obtained was stirred at high speed until a homogeneous paste was obtained.

With the paste obtained in this way, ceramic bodies were joined on their opposite surfaces to metal foils on both sides. For this purpose, ceramic bodies having the dimensions 174×139×0.32 mm (obtained from Toshiba Materials) and identical front and rear surface properties were used in each case. The paste was screen-printed onto the rear side of the ceramic bodies in a region of the dimensions 168×130 mm by means of a 280 mesh screen and pre-dried at 125° C. for 15 minutes. The paste thickness after pre-drying was 25+/−5 μm. Subsequently, a copper foil made of oxygen-free, highly conductive copper having a purity of 99.99% and a dimension of 170×132×0.3 mm was placed on the pre-dried paste. The arrangement thus produced was then turned around, the paste was likewise printed on the front side of the ceramic body, pre-dried and covered with a copper foil to obtain a sandwich arrangement. The sandwich arrangement was then weighted with a silicon carbide plate having a weight of 1 kg, fired at a maximum temperature of 910° C. (measured with a thermocouple) for 20 minutes and then cooled to room temperature to obtain a metal-ceramic substrate containing a ceramic layer that was bonded on both sides to a copper layer via a bonding layer.

### Examples for Etching the Metal-Ceramic Substrates

The metal-ceramic substrates obtained according to the above production example were provided with an etching mask on the upper side having masked and unmasked regions. After washing with water, the metal-ceramic substrates were treated with an etching solution 1 to remove copper from the copper layer and copper and tin from the bonding layer. Subsequently, the metal-ceramic substrates were washed and treated with etching solution 2 to remove titanium from the bonding layer according to the examples and comparative examples below.

### EXAMPLE 1

The metal-ceramic substrates were placed in a horizontal position on a conveyor belt and conveyed with the conveyor belt through a bath of etching solution 2.

### EXAMPLE 2

The metal-ceramic substrates were placed in a horizontal position on a conveyor belt and conveyed with the conveyor belt through a bath of etching solution 2 and treated with ultrasound in the process.

### EXAMPLE 3

The metal-ceramic substrates were placed in a horizontal position on a conveyor belt and conveyed under spray nozzles from which etching solution 2 was sprayed onto the metal-ceramic substrates.

### EXAMPLE 4

The metal-ceramic substrates were placed in a horizontal position on a conveyor belt and sprayed with an etching solution 2 while stationary.

### EXAMPLE 5

The metal-ceramic substrates were placed on a conveyor belt and conveyed with the conveyor belt through a bath of etching solution 2 and treated with ultrasound in the process. The metal-ceramic substrates and the conveying direction of the conveyor belt each formed an angle of 15°. The oblique positioning of the metal-ceramic substrates was achieved by means of a support. The metal-ceramic substrates were arranged such that an orthogonal projection of a metal-ceramic substrate onto a projection plane parallel to the masked metal layer of this metal-ceramic substrate shaded no more than 15% of the metal layer of another (adjacent) metal-ceramic substrate.

### EXAMPLE 6

The metal-ceramic substrates were placed on a conveyor belt and conveyed with the conveyor belt through a bath of etching solution 2 and treated with ultrasound in the process. The metal-ceramic substrates and the conveying direction of the conveyor belt each formed an angle of 10°. The oblique positioning of the metal-ceramic substrates was achieved by means of a support. The metal-ceramic substrates were arranged such that an orthogonal projection of a metal-ceramic substrate onto a projection plane parallel to the masked metal layer of this metal-ceramic substrate shaded no more than 50% of the metal layer of another (adjacent) metal-ceramic substrate.

### COMPARATIVE EXAMPLE 1

The metal-ceramic substrates were placed in a vertical position in a holder on a conveyor belt and conveyed with the conveyor belt through a bath of etching solution 2.

### COMPARATIVE EXAMPLE 2

The metal-ceramic substrates were placed in a vertical position in a holder on a conveyor belt and conveyed with the conveyor belt through a bath of etching solution 2 and treated with ultrasound in the process.

### COMPARATIVE EXAMPLE 3

The metal-ceramic substrates were placed in a vertical position in a holder on a conveyor belt and conveyed under spray nozzles from which etching solution 2 was sprayed onto the metal-ceramic substrates.

### COMPARATIVE EXAMPLE 4

The metal-ceramic substrates were placed in a vertical position in a holder on a conveyor belt and sprayed with an etching solution 2 while stationary.

### COMPARATIVE EXAMPLE 5

The metal-ceramic substrates were placed on a conveyor belt and conveyed with the conveyor belt through a bath of etching solution 2 and treated with ultrasound in the process. The metal-ceramic substrates and the conveying direction of the conveyor belt each formed an angle of 10°. The oblique positioning of the metal-ceramic substrates was achieved by means of a support. The metal-ceramic substrates were arranged such that an orthogonal projection of a metal-ceramic substrate onto a projection plane parallel to the masked metal layer of this metal-ceramic substrate shaded 70% of the metal layer of another (adjacent) metal-ceramic substrate.

### Evaluation:

The individual examples and comparative examples were repeated with different types of metal-ceramic substrates, with different types of etching solution 2 and at different conveyor belt speeds. The same aforementioned parameters were used for each example and comparative example. The amount of titanium remaining in the bonding layer of the metal-ceramic substrates was qualitatively determined. The results are listed in Table 1:

TABLE 1

| | | Amount of |
|---|---|---|
| Example | Shading | remaining titanium |
| Example 1 | 0% | ++ |
| Example 2 | 0% | +++ |
| Example 3 | 0% | ++ |
| Example 4 | 0% | ++ |
| Example 5 | 15% | +++ |
| Example 6 | 50% | ++ |
| Comparative | ~100% | − |
| example 1 | | |
| Comparative | ~100% | ∘ |
| example 2 | | |
| Comparative | ~100% | −− |
| example 3 | | |
| Comparative | ~100% | −− |
| example 4 | | |
| Comparative | 70% | ∘ |
| example 5 | | |

Meaning of symbols:
+++: very low residual titanium content
−−−: very high residual titanium content
∘: easily detectable residual titanium content

The results show that particularly effective removal of the active metal can be achieved if, during contacting with etching solution 2, the metal-ceramic substrates are arranged such that an orthogonal projection of a metal-ceramic substrate onto a projection plane parallel to the metal layer of said metal-ceramic substrate shades no more than 60% of the metal layer of a further metal-ceramic substrate, as is the case, for example, in a horizontal or virtually horizontal position of the metal-ceramic substrates in which they are separated. The results likewise show that the free active metal is virtually completely removed in a metal-ceramic substrate obtained by the method according to the invention.

1. A method for structuring metal-ceramic substrates, comprising the steps of:
a) providing a first metal-ceramic substrate and a second metal-ceramic substrate, each comprising
a ceramic layer,
a metal layer, and
a bonding layer located between the ceramic layer and the metal layer, wherein the bonding layer comprises (i) a metal having a melting point of at least 700° C. and (ii) an active metal,
b) providing an etching solution 1 that is capable of removing the metal from the metal layer and at least partly removing the metal having a melting point of at least 700° C. from the bonding layer,
c) providing an etching solution 2 that is capable of removing the active metal from the bonding layer,
d) masking regions on the metal layer of the first metal-ceramic substrate and on the metal layer of the second metal-ceramic substrate that are not intended to be removed,
e) contacting the first metal-ceramic substrate and the second metal-ceramic substrate with the etching solution 1, and
f) contacting the first metal-ceramic substrate and the second metal-ceramic substrate with the etching solution 2, wherein the first metal-ceramic substrate and the second metal-ceramic substrate are positioned such that an orthogonal projection of the first metal-ceramic substrate onto a projection plane parallel to the metal layer of the first metal-ceramic substrate shades no more than 60% of the metal layer of the second metal-ceramic substrate.

2. The method according to claim 1, wherein the ceramic of the ceramic layer is selected from the group consisting of aluminum nitride ceramics, silicon nitride ceramics and aluminum oxide ceramics.

3. The method according to claim 1, wherein the metal of the metal layer is copper.

4. The method according to claim 1, wherein the metal having a melting point of at least 700° C. is copper.

5. The method according to claim 1, wherein the bonding layer comprises a metal having a melting point of less than 700° C.

6. The method according to claim 5, wherein the metal having a melting point of less than 700° C. is selected from the group consisting of tin, bismuth, indium, gallium, zinc, antimony and magnesium.

7. The method according to claim 1, wherein the active metal is selected from the group consisting of titanium, zirconium, niobium, tantalum, vanadium and hafnium.

8. The method according to claim 1, wherein the maximum content of silver is 10.0 atomic percent and more preferably 1.0 atomic percent, based on the number of atoms in the bonding layer.

9. The method according to claim 1, wherein, while the first metal-ceramic substrate and the second metal-ceramic substrate are being contacted with the etching solution 2, the first metal-ceramic substrate and the second metal-ceramic substrate are positioned such that an orthogonal projection of the first metal-ceramic substrate onto a projection plane parallel to the metal layer of the first metal-ceramic substrate shades no more than 50%, preferably no more than 40%, particularly preferably no more than 30% and very particularly preferably no more than 15%, of the metal layer of the second metal-ceramic substrate.

10. The method according to claim 1, wherein, while being contacted with etching solution 2, the first metal-ceramic substrate and the second metal-ceramic substrate are positioned on a carrier, preferably on the same carrier.

11. The method according to claim 10, wherein the carrier is a conveyor belt that is moved in a conveying direction.

12. The method according to claim 11, wherein, while being contacted with the etching solution 2, the first metal-ceramic substrate and the second metal-ceramic substrate are positioned in at least one of the following ways:
a) the first metal-ceramic substrate and the second metal-ceramic substrate are not stacked;
b) the first metal-ceramic substrate and the second metal-ceramic substrate are arranged in a substantially horizontal position;
c) the first metal-ceramic substrate and the second metal-ceramic substrate are arranged in a substantially vertical position and one after another with respect to the conveying direction;
d) the first metal-ceramic substrate and the second metal-ceramic substrate are positioned such that the first metal-ceramic substrate and the conveying direction form an angle that is no more than 45°, more preferably no more than 30°, and even more preferably no more than 20°, and the second metal-ceramic substrate and the conveying direction form an angle that is no more than 45°, more preferably no more than 30°, and even more preferably no more than 20°.

13. A structured metal-ceramic substrate obtainable according to claim 1.
